(19) United States
(12) Patent Application Publication
(10) Pub. No.: US 2023/0253783 A1
(43) Pub. Date: Aug. 10, 2023

(54) METHOD FOR REDUCING IN-RUSH CURRENTS IN BATTERY CHARGING APPLICATIONS

(71) Applicant: HELLA GmbH & Co. KGaA, Lippstadt (DE)

(72) Inventor: Debabrato Kumar Mondal, Novi, MI (US)

(21) Appl. No.: 18/015,164

(22) PCT Filed: Jul. 29, 2021
(86) PCT No.: PCT/IB2021/056934

§ 371 Date: Jan. 9, 2023

Related U.S. Application Data
(60) Provisional application No. 63/059,223, filed on Jul. 31, 2020.

(51) Int. Cl. H02H 9/02; H01M 50/509; H01M 50/204; H02H 9/00; H02J 7/00

(52) U.S. Cl. CPC H02H 9/025; H01M 50/204; H01M 50/509; H02H 9/002; H02J 7/00304

(57) ABSTRACT

(57) Abstract: A system and a method for limiting in-rush currents to a battery module (14) is provided. The system and the method include operating a power MOSFET (12) with a pulse-width-modulated, PWM gate voltage. The frequency and the duty cycle of the PWM gate voltage are iteratively selected such that the current through the battery module (12) does not exceed a current limit value (18), the battery module (14) being series connected with the MOSFET load path. In one embodiment, the frequency and the duty cycle of the PWM gate voltage are alternatively varied to gradually increase the current in the load path until a current limit value (18) is reached.

### CROSS-REFERENCE TO RELATED APPLICATIONS

This application claims the benefit of U.S. Provisional Application 63/059,223, filed Jul. 31, 2020, the disclosure of which is incorporated by reference in its entirety.

### BACKGROUND OF THE INVENTION

The present invention relates to the operation of power MOSFETs in switching applications to reduce in-rush currents in cell/battery charging applications. The present invention is applicable with multiple cells that are present in a single battery module or multiple batteries connected in series or parallel. The present invention is also applicable in a central power supply module for managing multiple loads and for simultaneously charging multiple batteries. The present invention therefore adds more flexibility to generate multiple voltage sources from a single cell.

In many battery charging applications and in central power supply modules, a switching element is used to connect and disconnect a battery cell or a power supply module. For example, when a power supply module is replaced, the central power supply is ordinarily turned off. The input stage of the power supply module generally contains several initially uncharged bulk capacitors and EMI capacitors. Without any control, during first contact, these capacitors would experience a high surge current similar to a short circuit event. The current is only limited by the PCB parasitics of any other connected components such as resistances and inductances, with in-rush current being able to reach several hundred amperes or more. Although the energy is mainly drawn from the capacitor bank, the central power supply may collapse below a permissible level during this in-rush phase.

As a further example, assume an electric vehicle includes a power supply module having a battery cell/module at 14.5 V and a battery cell/module at 13 V. The power supply includes a first set of switches to couple the cells/modules in series and a second set of switches to couple the battery cells/modules in parallel, as generally set forth in US2018/0254658 to Koerner et al, the disclosure of which is incorporated by reference in its entirety. When the battery cells/modules are connected in parallel, there will be a high amount of current conducting between the two battery cells/modules.

Prior art solutions to the foregoing technical problems included the use of a dedicated charger for each battery module and/or the use of switches with an extremely high current rating. However, these prior art solutions are costly and can increase the size of the power supply beyond what is otherwise desired. Accordingly, there remains a continued need for an improved system and method for preventing in-rush currents in these and other applications.

### SUMMARY OF THE INVENTION

A system and a method for limiting in-rush currents to a battery module is provided. The system and the method include operating a power MOSFET with a pulse-width-modulated (PWM) gate voltage (V_{GS}). The frequency and the duty cycle of the PWM gate voltage (V_{GS}) are iteratively selected such that the current through the battery module does not exceed a current limit value, the battery module being series connected with the MOSFET load path. For example, the frequency and the duty cycle of the PWM gate voltage can be alternatively varied to gradually increase the current in the load path until a desired current limit value is reached. By controlling the input current to the battery module, the central power supply will not collapse and will instead allow charging of the battery module on-the-go, e.g., without a power down condition. An effective current limitation with an instant hot-swap capability is achieved by interposing the power MOSFET between a power supply and the battery module, the power MOSFET operating in the linear region and the saturation region during this short duration event. In series-to-parallel switching operations, a current-limiting behavior of the power MOSFET is utilized in the saturation region. As a result, the current can be controlled and slowly charge the battery cell having a lower voltage without the need of a buck converter. As the power MOSFET is activated, a thermal source is generated. This thermal source can be used to warm up the battery modules in cold temperatures to improve their reliability. If cranking fails due to low voltage, the present invention includes balancing the battery modules and thereby warming the battery modules to support the cranking current.

These and other features and advantages of the present invention will become apparent from the following description of the invention, when viewed in accordance with the accompanying drawings and the appended claim.

### BRIEF DESCRIPTION OF THE DRAWINGS

FIG. 1 is a functional block diagram of a control circuit for controlling operation of a power MOSFET for limiting in-rush currents to a battery module.

FIG. 2 is a circuit diagram including a battery module that is series connected with a load path of a PWM-controlled power MOSFET.

FIG. 3 is a flow chart illustrating frequency (f) and duty cycle (D) control of a power MOSFET for reducing in-rush current to a battery module.

FIG. 4 is a schematic diagram of a system of reducing in-rush currents to a battery cell during series-to-parallel switching operations.

### DETAILED DESCRIPTION OF THE PRESENT EMBODIMENT

In the present embodiment, a power MOSFET is used as a switch to control the flow of power to an electrical load, and in particular, a battery module. As is known in the art, a MOSFET is a three-terminal device in which the gate voltage controls the flow of current between a source and a drain. The system and method of the present invention limit in-rush currents to a battery module by iteratively varying the duty cycle (D) and frequency (f) of a pulse-width-modulated (PWM) gate voltage (V_{GS}), such that the frequency and duration of the individual control pulses and the time interval between two successive pulses can vary over time.

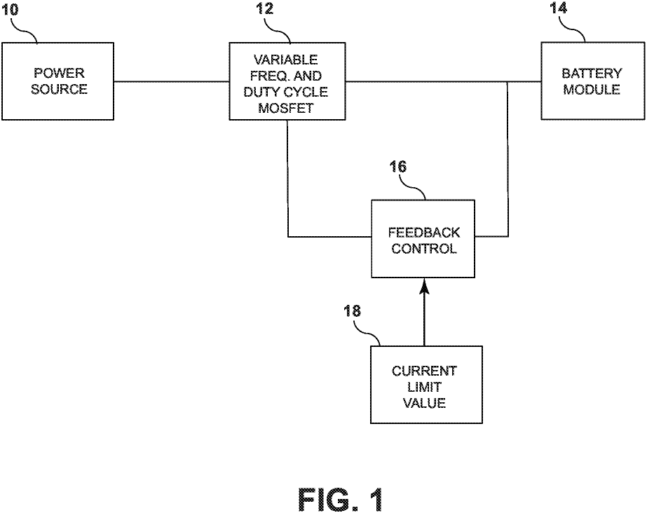

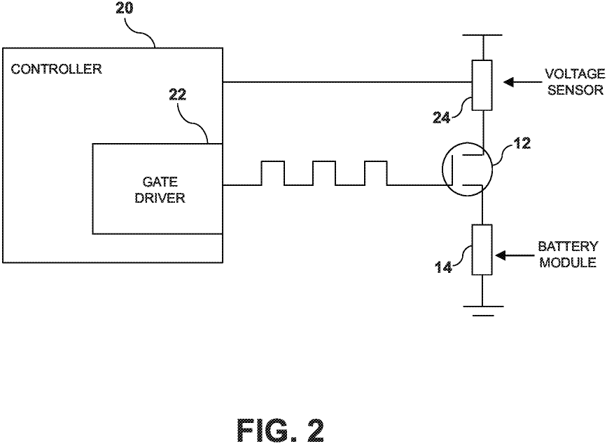

Referring now to FIG. 1, a control circuit in accordance with one embodiment is illustrated. The control circuit includes a power source 10, for example a DC voltage power supply. The power source 10 is electrically connected to a battery module 14 through power MOSFET 12, and in particular, a variable frequency and duty cycle power MOSFET 12. The power MOSFET 12 is coupled to a feedback circuit 16, which may be integrated into a controller 20 (shown in FIG. 2). The feedback circuit 16 measures the current in the MOSFET load path for comparison against a current limit value 18 stored to memory. Based on this comparison, the feedback circuit 16 varies the frequency and duty cycle of the PWM gate voltage (V_{GS}). As also shown in FIG. 2, the processor 20 includes a gate driver 22 coupled to the gate terminal of the power MOSFET 12 for generating the PWM gate voltage (V_{GS}). The controller 20 measures the current in the load path based on the output of a voltage sensor 24, for example a shunt resistor. In this embodiment, the battery module 14 is connected between the source terminal of the power MOSFET 12 and ground, but in other embodiments the battery module 14 is connected between the power source 10 and the drain terminal of the power MOSFET 12.

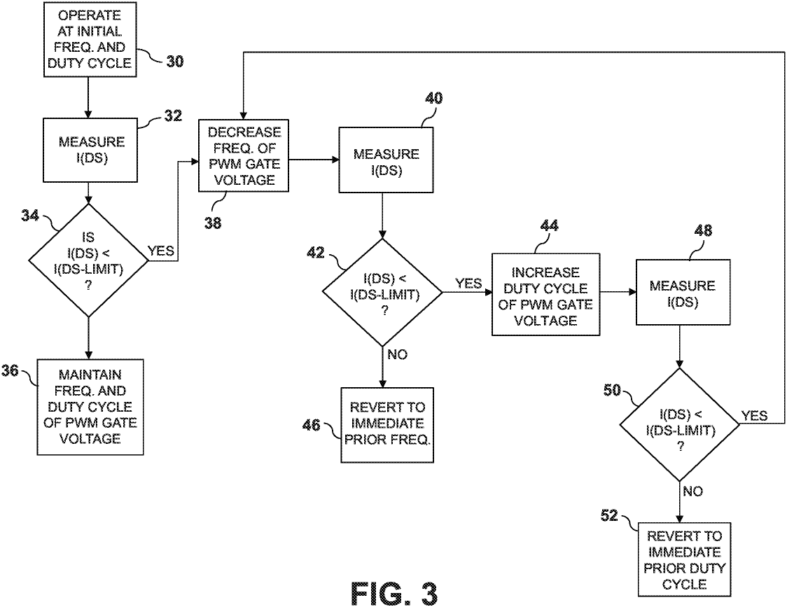

Operation of the above control circuits to limit in-rush currents is illustrated in connection with the functional block diagram of FIG. 3. The method includes activating the power MOSFET 12 with a pulse-width-modulated (PWM) gate voltage (V_{GS}) at a high baseline frequency (f) and a low baseline duty cycle (D) (step 30). The method then includes measuring the current (I_{DS}) in the load path (step 32). In the present embodiment, this measurement is performed by measuring the voltage across the shunt resistor 24 in FIG. 2, which as noted above is series-connected to the battery module 14. The measured current (I_{DS}) is then compared with a current limit value (I_{DS-Limit}) (step 34). If the measured current (I_{DS}) is not less than the current limit value (I_{DS-Limit}), the method includes maintaining the baseline frequency (f) and the baseline duty cycle (D) of the PWM gate voltage (V_{GS}) (step 36). If the measured current (I_{DS}) is less than the current limit value (I_{DS-Limit}), the method includes iteratively decreasing the frequency (f) and iteratively increasing the duty cycle (D) to gradually increase the current to the battery module 14.

In particular, if the measured current (I_{DS}) is less than the current limit value (I_{DS-Limit}), the method includes decreasing the baseline frequency of the PWM gate voltage (V_{GS}) (step 38). The load current (I_{DS}) is again measured (step 40) and compared with the current limit value (I_{DS-Limit}) (step 42). If the measured current (I_{DS}) is less than the current limit value (I_{DS-Limit}), the method includes decreasing the baseline frequency (f) of the PWM gate voltage (V_{GS}) (step 44); otherwise, the PWM gate voltage (V_{GS}) reverts to the prior frequency (f) (step 46). The load current (I_{DS}) is again measured (step 48) and compared with the current limit value (I_{DS-Limit}) (step 50). If the measured current (I_{DS}) is less than the current limit value (I_{DS-Limit}), the method includes decreasing the duty cycle (D) of the PWM gate voltage (V_{GS}) (step 38); otherwise, the PWM gate voltage (V_{GS}) reverts to the prior frequency (f) (step 52). In this respect, the load current (I_{DS}) through the battery module 14 is allowed to gradually increase until reaching the current limit value (I_{DS-Limit}) without a short circuit event that might otherwise damage the battery module 14.

The foregoing control circuit and method can be used to limit the in-rush current to an acceptable range. The forgoing control circuit and method can also be used in a central power supply module for managing multiple loads, for example when simultaneously charging multiple batteries. By controlling the input current, the central power supply will not collapse, and the changing of power modules on-the-go (e.g., without a power down condition) is made possible. In series-to-parallel switching operations, the current can be controlled and slowly charge the battery module having a lower voltage without the need of a buck converter. As the power MOSFET is activated, a thermal source is also generated. This thermal source can be used to warm up the battery modules in cold temperatures to improve their reliability. If cranking fails due to low voltage, the present invention includes balancing the battery modules and thereby warming the battery modules to support the cranking current.

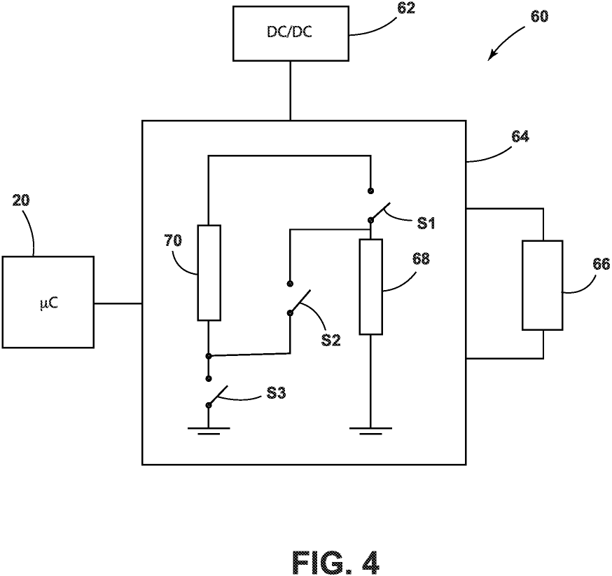

As further illustrated in FIG. 4, for example, a system for reducing in-rush currents is illustrated and generally designated 60. The system 60 includes a converter 62, a battery module 64, and an electrical load 66. The battery module 64 includes a first battery cell 68 and a second battery cell 70 that are connectable in series and in parallel through operation of a plurality of switches S1, S2, S3. Each of the switches are controlled by operation of a controller, for example the controller 20 of FIG. 2. For example, when switch S2 is closed and switches S1 and S3 are open, the first and second battery cells 68, 70 are connected in series. However, when switches S1 and S3 are closed and switch S2 is open, the first and second battery cells 68, 70 are connected in parallel. At least the first switch S1 is a power MOSFET, for example the power MOSFET 12 of FIG. 2. Because the second battery cell 70 (e.g., 14.5 V) can include a greater voltage than the first battery cell 68 (e.g., 13 V), the controller 20 can prevent an in-rush current during series-to-parallel switching operations by limiting the current through the first battery cell 68. In particular, the controller 20 provides a PWM gate voltage to the power MOSFET S1, wherein the PWM gate voltage includes a variable frequency and a variable duty cycle. The controller 20 includes machine readable instructions that, when executed, cause the controller to (i) measure a current in the load path of the power MOSFET S1 during activation of the power MOSFET and (ii) vary the frequency and the duty cycle of the PWM gate voltage to iteratively increase the current in the load path of the power MOSFET S1 while maintaining the current in the load path of the power MOSFET below a current limit value. As set forth above in connection with FIG. 3, varying the frequency and the duty cycle of the PWM gate voltage of the power MOSFET S1 includes alternatively decreasing the frequency of the PWM gate voltage and increasing the duty cycle of the PWM gate voltage. The controller 20 compares the current in the load path with the current limit value after decreasing the frequency of the PWM gate voltage and after increasing the duty cycle of the PWM gate voltage. By controlling the input current to the first battery cell 68, the central power supply will not collapse and will instead allow charging of the first battery cell 68 on-the-go, e.g., without a power down condition. As a result, the current can be controlled and slowly charge the battery cell having a lower voltage without the need of a buck converter. In addition, as the power MOSFET is activated, a thermal source is generated. This thermal source can be used to warm up the battery module 64 in cold temperatures to improve its reliability. If cranking fails due to low voltage, the present invention includes balancing the battery cells 68, 70 and thereby warming the battery module 64 to support the cranking current.

The above description is that of a current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A method comprising:
providing a battery module including a first battery cell that is series connected with a load path of a power MOSFET;
activating the power MOSFET with a PWM gate voltage, the PWM gate voltage having a variable frequency and a variable duty cycle;
measuring the current in the load path of the power MOSFET during activation of the power MOSFET; and
varying the frequency and the duty cycle of the PWM gate voltage to iteratively increase the current in the load path of the power MOSFET while maintaining the current in the load path of the power MOSFET below a current limit value.

2. The method of claim 1, wherein varying the frequency and the duty cycle of the PWM gate voltage includes alternatively decreasing the frequency of the PWM gate voltage and increasing the duty cycle of the PWM gate voltage.

3. The method of claim 2, further including comparing the current in the load path with the current limit value after decreasing the frequency of the PWM gate voltage and after increasing the duty cycle of the PWM gate voltage.

4. The method of claim 1, wherein the battery module includes a second battery cell having a series connection with the first battery cell, wherein activating the power MOSFET converts the series connection into a parallel connection for charging the first battery cell.

5. The method of claim 4, further including connecting an electrical load across the first and second battery cells when the first and second battery cells are connected in series.

6. The method of claim 4, further including connecting an electrical load across the first and second battery cells when the first and second battery cells are connected in parallel.

7. The method of claim 4, wherein the current through the first battery cell is less than the current limit value when the first and second battery cells are connected in parallel.

8. The method of claim 4, further including a DC/DC converter coupled to the battery module for charging the first and second battery cells.

9. The method of claim 1, wherein measuring the current in the load path is performed in digital logic based on the output of a voltage sensor.

10. A system comprising:
a battery module including a first battery cell;
a power MOSFET, the first battery cell being series connected with a load path of the power MOSFET; and
a controller adapted to provide a PWM gate voltage to the power MOSFET, wherein the PWM gate voltage includes a variable frequency and a variable duty cycle, the controller including machine readable instructions that, when executed, cause the controller to (i) measure a current in the load path of the power MOSFET during activation of the power MOSFET and (ii) vary the frequency and the duty cycle of the PWM gate voltage to iteratively increase the current in the load path of the power MOSFET while maintaining the current in the load path of the power MOSFET below a current limit value.

11. The system of claim 10, wherein the battery module includes a second battery cell having a series connection with the first battery cell, wherein activating the power MOSFET converts the series connection into a parallel connection for charging the first battery cell.

12. The system of claim 11, further including a DC/DC converter coupled to the battery module for charging the first and second battery cells.

13. The system of claim 10, wherein varying the frequency and the duty cycle of the PWM gate voltage includes alternatively decreasing the frequency of the PWM gate voltage and increasing the duty cycle of the PWM gate voltage.

14. The system of claim 10, wherein the machine readable instructions further cause the controller to compare the current in the load path with the current limit value after decreasing the frequency of the PWM gate voltage and after increasing the duty cycle of the PWM gate voltage.

15. The system of claim 10, wherein the controller is coupled to the output of a voltage sensor to indirectly measure the current in the load path of the power MOSFET.
